(19) United States
(12) Patent Application Publication
(10) Pub. No.: US 2026/0101517 A1
(43) Pub. Date: Apr. 9, 2026

(54) SEMICONDUCTOR DEVICE

(71) Applicant: SK hynix Inc., Icheon-si Gyeonggi-do (KR)

(72) Inventor: Heon Yong CHANG, Icheon-si Gyeonggi-do (KR)

(73) Assignee: SK hynix Inc., Icheon-si Gyeonggi-do (KR)

(21) Appl. No.: 19/084,532

(22) Filed: Mar. 19, 2025

(30) Foreign Application Priority Data
Sep. 30, 2024 (KR) 10-2024-0132989

(51) Int. Cl. H01L 23/00; H01L 21/66; H01L 23/58; H01L 25/18; H10B 80/00

(52) U.S. Cl. CPC H10B 80/00; H10P 74/27; H10W 42/00; H10W 72/0198; H10W 72/952; H10W 90/00; H10W 90/792

(57) ABSTRACT

A semiconductor device according to an embodiment of the present disclosure includes a guard area, a chip area surrounded by the guard area, and a circuit structure including bonding pads coupled in series in the chip area. A semiconductor device according to an embodiment of the present disclosure includes a chip area, chip guards surrounding the chip area and spaced apart from each other, and a circuit structure including bonding pads coupled in series between the chip guards.

### CROSS-REFERENCE TO RELATED APPLICATION

The present application claims priority under 35 U.S.C. § 119(a) to Korean patent application number 10-2024-0132989 filed on Sep. 30, 2024, in the Korean Intellectual Property Office, the entire contents of which application is incorporated herein by reference.

### BACKGROUND

### 1. Technical Field

Various embodiments of the present disclosure generally relate to a semiconductor device, and more particularly, to a semiconductor device including a test circuit configured to detect whether bonding is achieved in a wafer bonding structure.

### 2. Related Art

Through a semiconductor integration process, a plurality of chip areas may be formed over a semiconductor substrate. The plurality of chip areas may be separated from each other by a scribe lane area. A plurality of semiconductor chips may be manufactured by separating the plurality of chip areas from each other through a cutting process.

Because an improvement in integration degree of a three-dimensional non-volatile memory device in which memory cells are stacked in a vertical direction on a substrate has been limited, a method of forming more circuits in a limited chip area has been proposed. For example, there has been proposed a wafer bonding structure in which a first wafer, on which a peripheral circuit is formed, is bonded to a second wafer on which memory cells are formed.

### SUMMARY

According to an embodiment, a semiconductor device may include a guard area, a chip area surrounded by the guard area, and a circuit structure including bonding pads coupled in series in the chip area.

According to an embodiment, a semiconductor device may include a chip area, chip guards surrounding the chip area and spaced apart from each other, and a circuit structure including bonding pads coupled in series between the chip guards.

According to an embodiment, a semiconductor device may include a lower structure including a peripheral circuit, an upper structure stacked over the lower structure and including a memory cell array, lower bonding pads exposed to an upper surface of the lower structure, upper bonding pads exposed to a lower surface of the upper structure and contacting the lower bonding pads, respectively, and test electrodes coupled to one or more of the upper bonding pads in the upper structure, wherein the upper bonding pads and the lower bonding pads are coupled in series to form an electrical path.

According to an embodiment, a semiconductor device may include an upper structure stacked over the lower structure and including a memory cell array, first lower bonding pads exposed to an upper surface of the lower structure, first upper bonding pads exposed to a lower surface of the upper structure and contacting the first lower bonding pads, respectively, and test electrodes coupled to one or more of the first upper bonding pads in the upper structure, wherein the first upper bonding pads and the first lower bonding pads are coupled in series to form an electrical path, and wherein the electrical path surrounds the memory cell array.

### BRIEF DESCRIPTION OF THE DRAWINGS

FIG. 1 is a diagram illustrating a structure of a semiconductor device according to an embodiment of the present disclosure;

FIGS. 2A, 2B, 2C, and 2D are diagrams illustrating a structure of a semiconductor device according to first embodiments of the present disclosure;

FIGS. 3A, 3B, 3C, 3D, and 3E are diagrams illustrating a method of manufacturing the semiconductor device according to the first embodiments of the present disclosure;

FIGS. 4A, 4B, 4C, and 4D are diagrams illustrating various embodiments related to the first embodiments of the present disclosure;

FIGS. 5A, 5B, and 5C are diagrams illustrating a structure of a semiconductor device according to second embodiments of the present disclosure;

FIGS. 6A, 6B, 6C, 6D, 6E, and 6F are diagrams illustrating a method of manufacturing the semiconductor device according to the second embodiments of the present disclosure;

FIGS. 7A, 7B, 7C, and 7D are diagrams illustrating various embodiments related to the second embodiments of the present disclosure;

FIGS. 8A, 8B, 8C, and 8D are diagrams illustrating a memory device including a circuit structure according to an embodiment of the present disclosure;

FIG. 9 is a diagram illustrating a memory card system to which a memory device according to an embodiment of the present disclosure is applied; and

FIG. 10 is a diagram illustrating a solid state drive (SSD) system to which a memory device according to an embodiment of the present disclosure is applied.

### DETAILED DESCRIPTION

Specific structural or functional descriptions disclosed herein are merely illustrative for the purpose of describing embodiments according to the concept of the present disclosure. Embodiments according to the concept of the present disclosure may be implemented in various forms and should not be construed as being limited to the specific embodiments set forth herein. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present. Terms such as “first,” “second,” etc., are used to distinguish between various elements and do not imply size, order, priority, quantity, or importance of the elements. For example, a first element may be named as a second element in one example, and the second element may be named as a first element in another example. Terms such as “top,” “over,” “on,” “side,” “upper,” “lower,” “row,” “column,” “inner,” “outer” and other terms implying relative spatial relationship or orientation are utilized only for the purpose of ease of description or reference to a drawing and are not otherwise limiting. The cross-hatching throughout the figures illustrates corresponding or similar areas between the figures rather than indicating the materials associated with the areas.

Hereinafter, embodiments of the present disclosure will be described in detail with reference to the accompanying drawings in order for those skilled in the art to be able to implement the technical spirit of the present disclosure.

Various embodiments of the present disclosure are directed to a semiconductor device capable of more easily detecting whether or not bonding pads are bonded to each other.

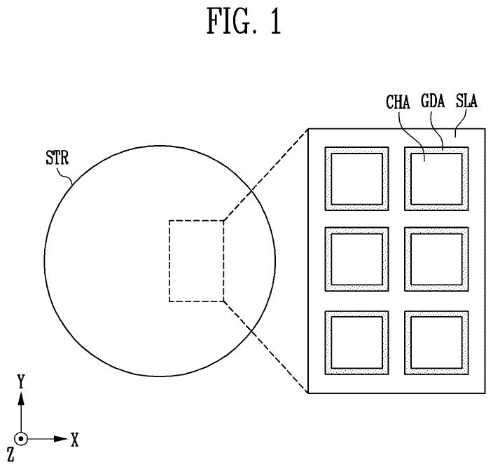

FIG. 1 is a diagram illustrating a structure of a semiconductor device according to an embodiment of the present disclosure.

The semiconductor device may include a structure STR. For example, the structure STR may include a substrate (e.g., a silicon wafer, a SiGe wafer, or a SOI wafer) and material patterns formed over the substrate.

Referring to FIG. 1, the structure STR may include chip areas CHA, guard areas GDA, and a scribe lane area SLA. For example, the structure STR may include the chip areas CHA, the guard areas GDA which respectively surround the chip areas CHA, and the scribe lane area SLA which surrounds the guard areas GDA.

Semiconductor chips may be formed in the chip areas CHA. The chip areas CHA may be arranged in an X direction and a Y direction. Each of the semiconductor chips may be formed through a semiconductor integration process performed on the chip areas CHA. For example, when the semiconductor chips formed in the chip areas CHA include a memory cell array, the semiconductor device may be a memory device. In a single structure STR, the semiconductor chips formed in the chip areas CHA, respectively, may be substantially the same. After the semiconductor integration process is completed on the substrate, the structure STR may be separated into the chip areas CHA such that each of the chip areas CHA is separated into the shape of the semiconductor chip.

Each of the guard areas GDA may be adjacent to each of the chip areas CHA. Each of the guard areas GDA may surround each of the chip areas CHA. For example, the guard area GDA may be formed within a predetermined distance from the boundary of the chip area CHA. When the chip area CHA has a rectangular shape in a plan view, the guard area GDA may have a hollow rectangular shape to surround the chip area CHA in a plan view. A side surface of the chip area CHA and an inner surface of the guard area GDA may contact each other. The word “predetermined” as used herein with respect to a parameter, such as a predetermined distance, thickness, or range, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm.

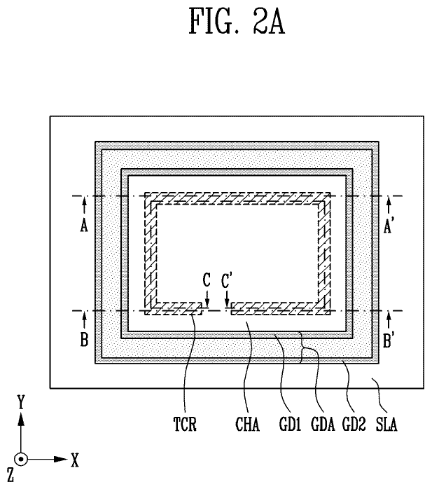

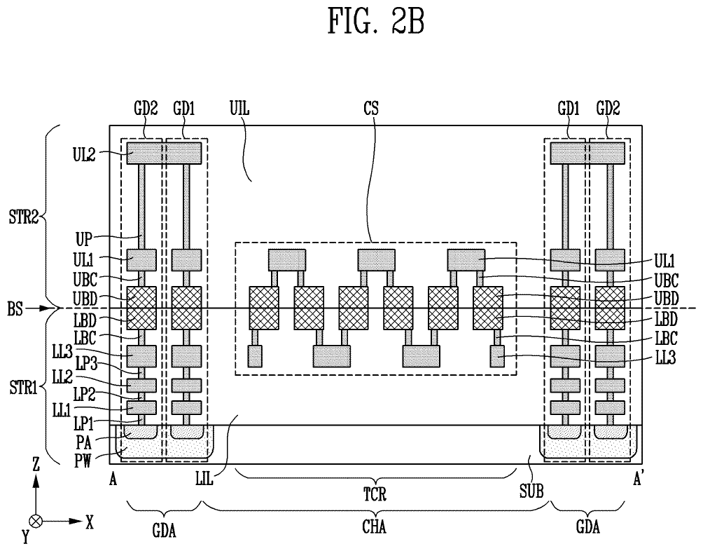

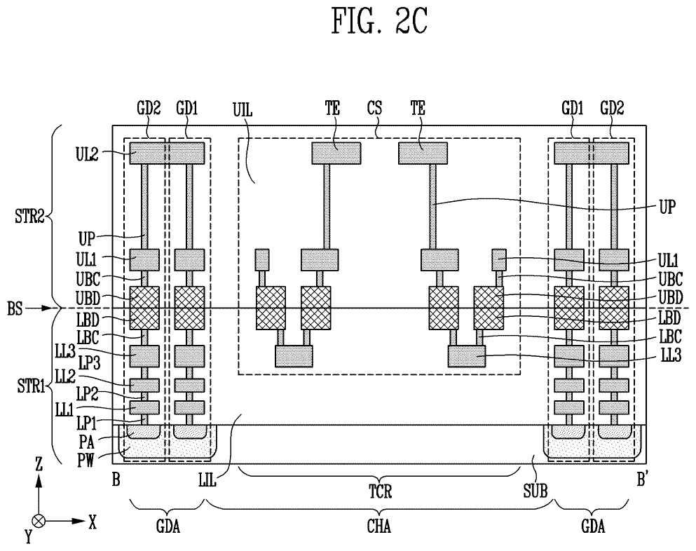

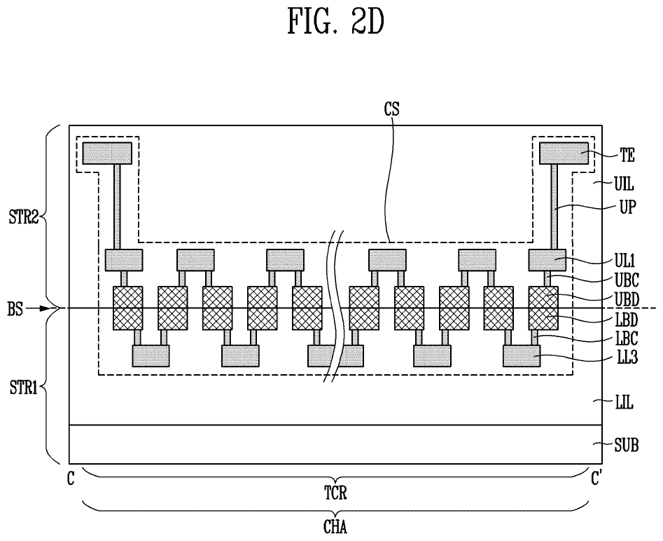

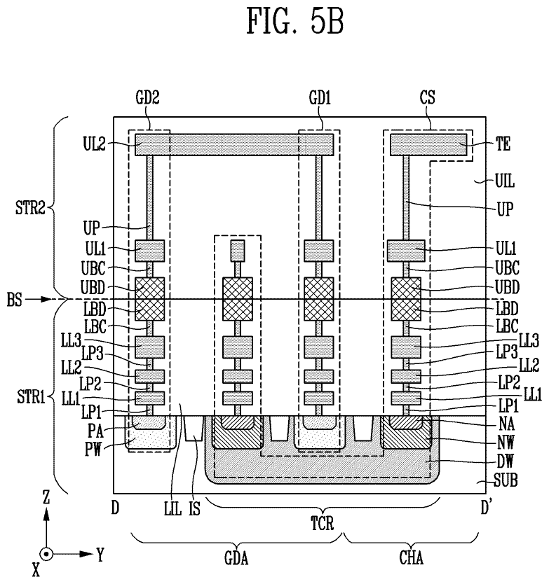

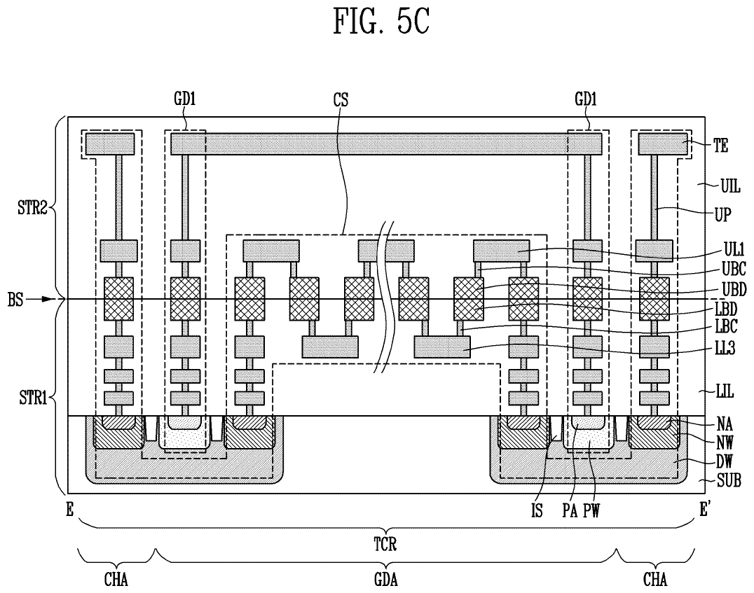

Chip guards may be formed in the guard areas GDA. In an embodiment, the chip guards may prevent or mitigate moisture or oxygen from penetrating from the outside of the chip area CHA into the chip area CHA. In addition, in an embodiment, the chip guards may reduce interference between dies in a packaging process, which is performed after the chip areas CHA have been divided into respective semiconductor chips. The shapes of the chip guards will be described below with reference to FIGS. 2B, 2C, 5B, and 5C.

A circuit structure may be disposed in the chip area CHA or the guard area GDA. The circuit structure may serve as a test circuit to detect whether bonding is achieved in a semiconductor device with a wafer bonding structure. The location and shape of the circuit structure will be described below with reference to FIGS. 2A to 2D, 4A to 4D, 5A to 5C, and 7A to 7D.

The scribe lane area SLA may be located outside the chip areas CHA and the guard areas GDA. For example, the scribe lane area SLA may be located between the chip areas CHA. In addition, the scribe lane area SLA may surround the guard areas GDA. After the semiconductor integration process is completed, the scribe lane area SLA may be cut during a dicing process to separate the semiconductor chips. Because the structure STR is cut along the scribe lane area SLA, the chip areas CHA may be separated from each other. Each separated semiconductor chip may include one chip area CHA and one guard area GDA which surrounds the one chip area CHA. Various methods, such as a sawing process using blades, a laser process utilizing lasers, or a stealth dicing process, may be used to cut the structure STR. In an embodiment, electrical test patterns, process monitoring patterns, and alignment keys may be disposed in the scribe lane area SLA.

In FIG. 1, six chip areas CHA are shown for convenience of description, but the scope of the present disclosure is not limited thereto. For example, the structure STR may include seven or more chip areas CHA. In the present disclosure, the chip areas CHA, the guard areas GDA, and the scribe lane area SLA are illustrated as being divided from each other for convenience of description, but the chip areas CHA, the guard areas GDA, and the scribe lane area SLA might not be physically separated from each other and consecutively coupled to each other. For example, the boundaries of the chip areas CHA, the guard areas GDA, and the scribe lane area SLA might not be clearly observed. In addition, the locations of the chip areas CHA, the guard areas GDA, and the scribe lane area SLA in the structure STR may be determined randomly. In the present disclosure, the chip areas CHA, the guard areas GDA, and the scribe lane area SLA may refer to spaces where a range in a horizontal direction is limited to a predetermined range in the structure STR, not areas in the substrate.

FIGS. 2A to 2D are diagrams illustrating a structure of a semiconductor device according to first embodiments of the present disclosure. FIG. 2A is a plan view of a layout of the semiconductor device according to the first embodiments of the present disclosure. FIG. 2B is a cross-sectional view taken along line A-A′ of FIG. 2A. FIG. 2C is a cross-sectional view taken along line B-B′ of FIG. 2A. FIG. 2D is a cross-sectional view taken along line C-C′ of FIG. 2A.

Referring to FIG. 2A, a first chip guard GD1 and a second chip guard GD2 may be formed in the guard area GDA. The guard area GDA may include the first chip guard GD1, the second chip guard GD2, and an area located between the first chip guard GD1 and the second chip guard GD2. The chip area CHA may be surrounded by the first chip guard GD1. For example, the first chip guard GD1 may have a rectangular shape extending along the boundary of the chip area CHA in a plan view. The scribe lane area SLA may be located outside the second chip guard GD2. For example, the second chip guard GD2 may have a rectangular shape which is greater in area than that of the first chip guard GD1 in a plan view.

A test circuit area TCR may be located in the chip area CHA. The test circuit area TCR may be adjacent to the guard area GDA in the chip area CHA. The test circuit area TCR may extend along the boundary of the chip area CHA. The test circuit area TCR may extend along at least three side surfaces among four side surfaces of the chip area CHA. For example, the chip area CHA may include a first area which includes a center of the chip area CHA and a second area which surrounds the first area, and the test circuit area TCR may be located in the second area of the chip area CHA. The test circuit area TCR may surround the first area of the chip area CHA. The test circuit area TCR may have a rectangular shape with some portions being disconnected in a plan view.

Referring to FIG. 2B, the semiconductor device may include a lower structure STR1 and an upper structure STR2 over the lower structure STR1. The upper structure STR2 may be located in a Z direction with respect to the lower structure STR1. The upper structure STR2 may be stacked over the lower structure STR1. A lower surface of the upper structure STR2 may contact an upper surface of the lower structure STR1. The lower structure STR1 and the upper structure STR2 may contact each other on a bonding surface BS. The lower structure STR1 and the upper structure STR2 may be bonded to each other on the bonding surface BS. The upper structure STR2 may be bonded to the lower structure STR1 through a wafer boding method.

The lower structure STR1 may include a substrate SUB. The substrate SUB may extend from the chip area CHA to the guard area GDA. The substrate SUB may extend in the X and Y directions. For example, the substrate SUB may be a silicon wafer substrate, a SiGe wafer substrate, or a SOI wafer substrate, etc.

The substrate SUB may include a first well area PW and a first activation area PA. The first well area PW and the first activation area PA may be areas of the substrate SUB into which a first type of impurity is injected. The amount of the impurity included in the first activation area PA may be greater than the amount of the impurity included in the first well area PW. The first type of impurity may include an element of group 13. For example, the first type of impurity may include boron (B) or indium (In).

The first well area PW and the first activation area PA may be located in the guard area GDA. The first well area PW and the first activation area PA may extend in the horizontal direction. For example, the first well area PW and the first activation area PA which are located in the X direction with respect to the chip area CHA may extend in the Y direction. In an embodiment, a portion of the first well area PW may extend into the chip area CHA.

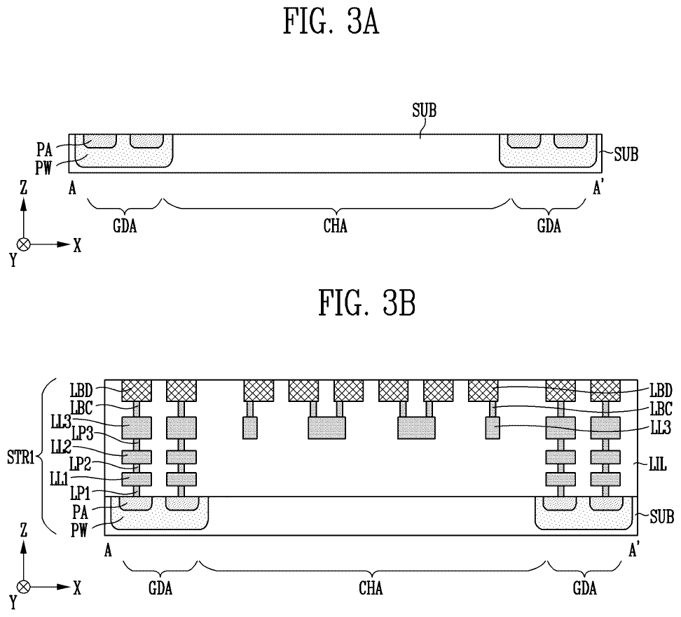

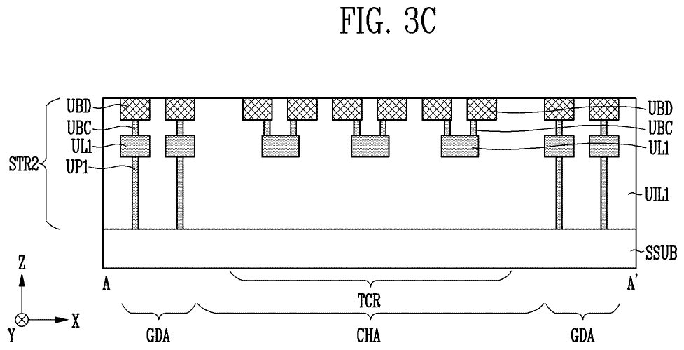

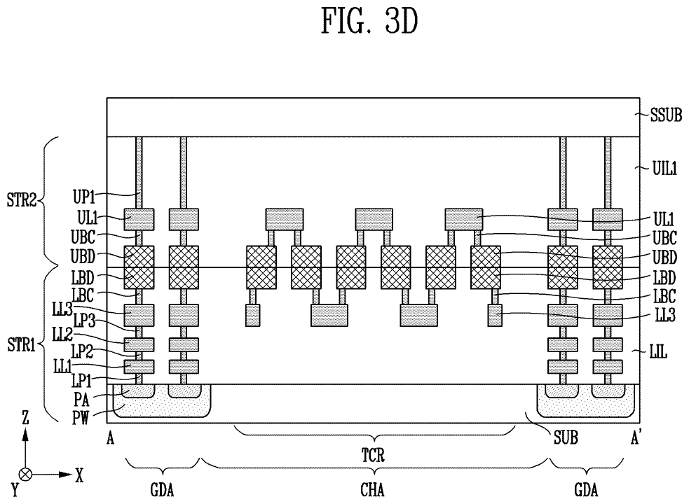

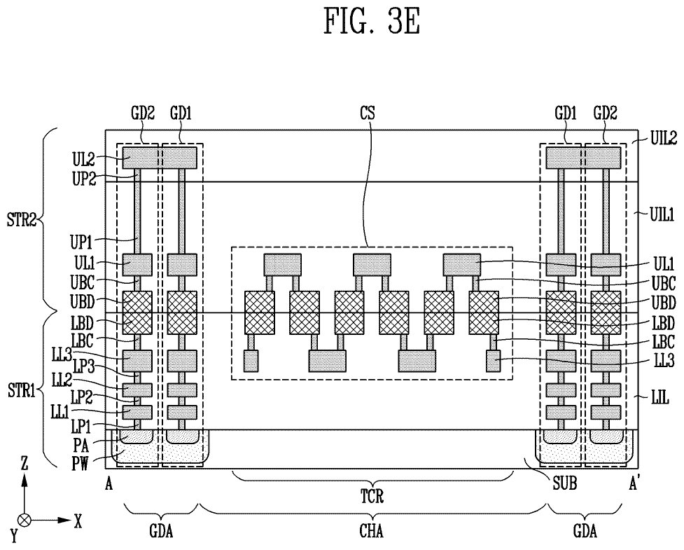

The upper structure STR2 might not include any substrates. The upper structure STR2 which does not include any substrates will be described below with reference to FIGS. 3D and 3E.

The lower structure STR1 may include lower bonding pads LBD which are exposed to the upper surface of the lower structure STR1. The lower bonding pads LBD may be disposed in the chip area CHA and the guard area GDA. The lower bonding pads LBD may include a conductive material. For example, the lower bonding pads LBD may include copper (Cu).

The lower structure STR1 may include a lower insulating layer LIL. The lower insulating layer LIL may be located over the substrate SUB. The lower insulating layer LIL may be located between the lower bonding pads LBD. The lower bonding pads LBD may be separated from each other by the lower insulating layer LIL. The lower insulating layer LIL may include an insulating layer (e.g., an oxide layer).

The upper structure STR2 may include upper bonding pads UBD which are exposed to the lower surface of the upper structure STR2. The upper bonding pads UBD may be disposed in the chip area CHA and the guard area GDA. The upper bonding pads UBD may include a conductive material. The upper bonding pads UBD may include the same material as the lower bonding pads LBD. For example, the upper bonding pads UBD may include copper (Cu).

The upper bonding pads UBD may contact the lower bonding pads LBD. The upper bonding pads UBD and the lower bonding pads LBD may contact each other on the bonding surface BS. The upper bonding pads UBD and the lower bonding pads LBD may be electrically coupled to each other. The upper bonding pads UBD and the lower bonding pads LBD may be bonded to each other. The lower bonding pads LBD may overlap the upper bonding pads UBD, respectively. Alternatively, the upper bonding pads UBD may overlap the lower bonding pads LBD, respectively.

The upper structure STR2 may include an upper insulating layer UIL. The upper insulating layer UIL may be located between the upper bonding pads UBD. The upper bonding pads UBD may be separated from each other by the upper insulating layer UIL. The upper insulating layer UIL may include an insulating layer (e.g., an oxide layer).

The upper insulating layer UIL may contact the lower insulating layer LIL. The upper insulating layer UIL and the lower insulating layer LIL may contact each other on the bonding surface BS. The upper insulating layer UIL and the lower insulating layer LIL may be bonded to each other.

The first and second chip guards GD1 and GD2 may be located in the guard area GDA. Each of the first and second chip guards GD1 and GD2 may extend in the Z direction. Each of the first and second chip guards GD1 and GD2 may extend in the Z direction in the lower structure STR1. In addition, each of the first and second chip guards GD1 and GD2 may extend in the Z direction in the upper structure STR2. In an embodiment, each of the first and second chip guards GD1 and GD2 may have a shape which extends in the Z direction to prevent or mitigate moisture or oxygen from penetrating from the outside of the chip area CHA into the chip area CHA.

The first and second chip guards GD1 and GD2 may extend in the horizontal direction. For example, a portion of the first chip guard GD1 which is located in the X direction with respect to the chip area CHA may extend in the Y direction. The first chip guard GD1 may extend in a direction in which the side surface of the chip area CHA extends. The second chip guard GD2 may extend in a direction in which the first chip guard GD1 extends.

Each of the first and second chip guards GD1 and GD2 may include the first well area PW and the first activation area PA in the substrate SUB. The first well area PW included in the first chip guard GD1 and the first well area PW included in the second chip guard GD2 may be coupled to each other. In another embodiment, the first well area PW included in the first chip guard GD1 and the first well area PW included in the second chip guard GD2 may be separated from each other. In addition, each of the first and second chip guards GD1 and GD2 may include the lower bonding pads LBD in the guard area GDA. Each of the first and second chip guards GD1 and GD2 may include a first lower plug LP1, a first lower line LL1, a second lower plug LP2, a second lower line LL2, a third lower plug LP3, a third lower line LL3, and a lower bonding contact LBC located between the first activation area PA and the lower bonding pad LBD. The first lower plug LP1, the first lower line LL1, the second lower plug LP2, the second lower line LL2, the third lower plug LP3, the third lower line LL3, and the lower bonding contact LBC may be sequentially disposed in the Z direction over the first activation area PA. The first lower plug LP1, the first lower line LL1, the second lower plug LP2, the second lower line LL2, the third lower plug LP3, the third lower line LL3, the lower bonding contact LBC, and the lower bonding pad LBD may be surrounded by the lower insulating layer LIL.

Each of the first and second chip guards GD1 and GD2 may include the upper bonding pads UBD in the guard area GDA. Each of the first and second chip guards GD1 and GD2 may include an upper bonding contact UBC, a first upper line UL1, an upper plug UP, and a second upper line UL2 located over the upper bonding pad UBD. The upper bonding contact UBC, the first upper line UL1, the upper plug UP, and the second upper line UL2 may be sequentially disposed in the Z direction over the upper bonding pad UBD. The upper bonding pad UBD, the upper bonding contact UBC, the first upper line UL1, the upper plug UP, and the second upper line UL2 may be surrounded by the upper insulating layer UIL. The second upper line UL2 included in the first chip guard GD1 and the second upper line UL2 included in the second chip guard GD2 may be coupled to each other. In an embodiment, the second upper line UL2 included in the first chip guard GD1 and the second upper line UL2 included in the second chip guard GD2 may be separated from each other.

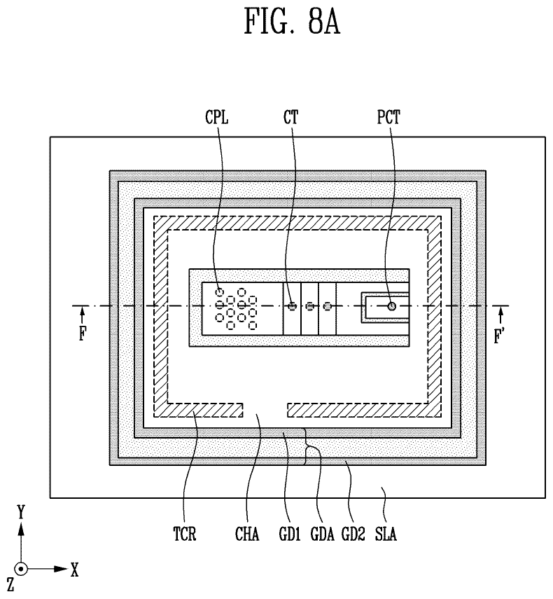

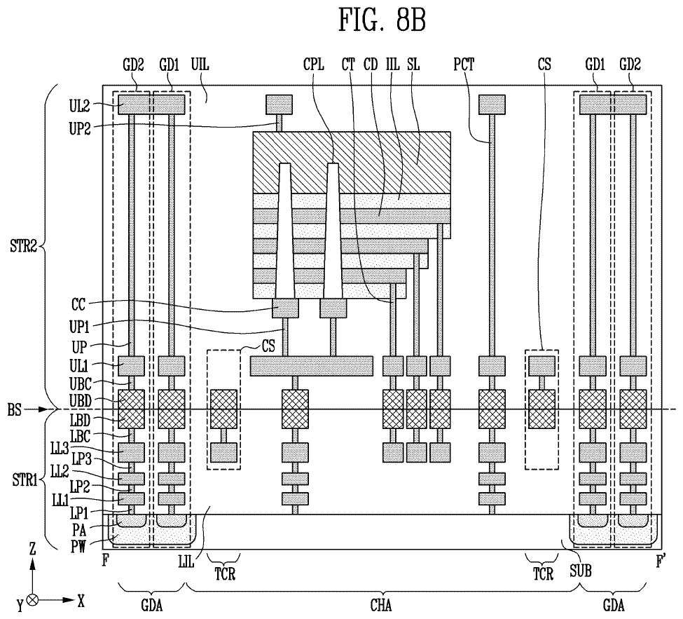

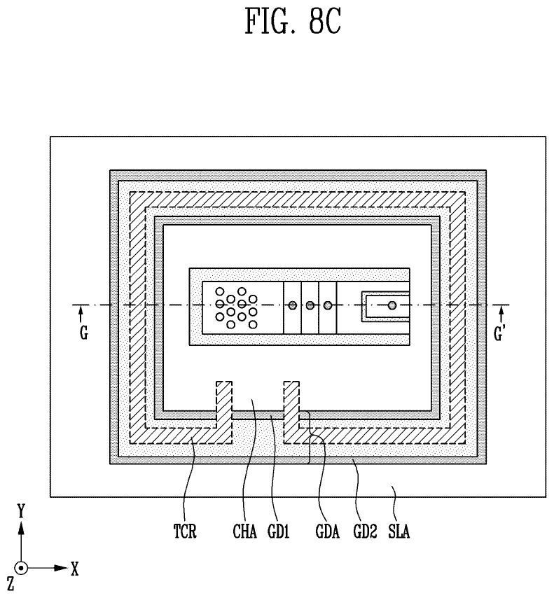

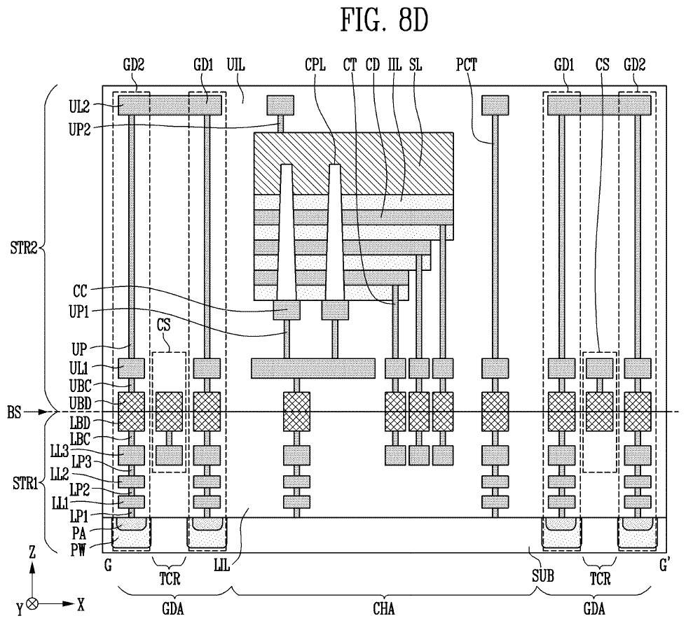

A circuit structure CS may be located in the test circuit area TCR. Referring to FIGS. 2A and 2B together, the circuit structure CS may extend along an interface between the chip area CHA and the guard area GDA. For example, the chip area CHA may have a rectangular shape in a plan view and the circuit structure CS may have a shape which corresponds to a portion of the rectangular shape. Though not shown in FIGS. 2A and 2B, the chip area CHA may include the first area which includes the center of the chip area CHA and the second area which surrounds the first area. The circuit structure CS may be disposed in the second area of the chip area CHA. In addition, the memory cell array may be disposed in the first area of the chip area CHA. The circuit structure CS may be disposed between the memory cell array and the guard area GDA. The circuit structure CS may surround the memory cell array. The relationship between the memory cell array and the circuit structure CS in terms of location will be described below with reference to FIGS. 8A to 8D.

Referring back to FIG. 2B, the circuit structure CS may include the bonding pads (e.g., the upper bonding pads UBD and the lower bonding pads LBD) in the chip area CHA. The circuit structure CS may include the upper bonding pads UBD and the lower bonding pads LBD disposed in the chip area CHA. The upper bonding pads UBD included in the circuit structure CS may overlap with the lower bonding pads LBD included in the circuit structure CS in a one-to-one manner. The upper bonding pad UBD and the lower bonding pad LBD which contact each other may be referred to as one bonding pad group. The circuit structure CS may include bonding pad groups that are arranged in the X and Y directions in the chip area CHA. For example, the bonding pad groups may be arranged in a row in the X direction in FIG. 2B.

The bonding pads (e.g., the upper bonding pads UBD and the lower bonding pads LBD) included in the circuit structure CS may be coupled in series. The upper bonding pads UBD and the lower bonding pads LBD included in the circuit structure CS may be electrically coupled to each other.

The lower structure STR1 may include the lower bonding contacts LBC each contacting a corresponding one of the lower bonding pads LBD. Each of the lower bonding contacts LBC may contact a lower surface of each of the lower bonding pads LBD. The lower bonding contacts LBC may be electrically coupled to the lower bonding pads LBD, respectively. The lower bonding contacts LBC may include a conductive material. The lower structure STR1 may include the third lower lines LL3 each of which couples at least two lower bonding contacts LBC among the lower bonding contacts LBC. In the test circuit area TCR, each of the third lower lines LL3 may contact the lower surfaces of at least two lower bonding contacts LBC. In the test circuit area TCR, the third lower lines LL3 may electrically couple adjacent lower bonding contacts LBC to each other. The third lower lines LL3 may include a conductive material.

The upper structure STR2 may include the upper bonding contacts UBC each contacting a corresponding one of the upper bonding pads UBD. Each of the upper bonding contacts UBC may contact an upper surface of each of the upper bonding pads UBD. The upper bonding contacts UBC may be electrically coupled to the upper bonding pads UBD, respectively. The upper bonding contacts UBC may include a conductive material. The upper structure STR2 may include the first upper lines UL1 each of which couples at least two upper bonding contacts UBC among the upper bonding contacts UBC. In the test circuit area TCR, each of the first upper lines UL1 may contact the upper surfaces of at least two upper bonding contacts UBC. In the test circuit area TCR, the first upper lines UL1 may electrically couple adjacent upper bonding contacts UBC to each other. The first upper lines UL1 may include a conductive material.

Referring to FIG. 2B, the third lower lines LL3, the lower bonding contacts LBC, the lower bonding pads LBD, the upper bonding pads UBD, the upper bonding contacts UBC, and the first upper lines UL1 included in the circuit structure CS may be coupled to each other in series. The third lower lines LL3, the lower bonding contacts LBC, the lower bonding pads LBD, the upper bonding pads UBD, the upper bonding contacts UBC, and the first upper lines UL1 included in the circuit structure CS may be coupled to each other in a chain form.

Referring to FIG. 2C, the circuit structure CS may include test electrodes TE. The test electrodes TE may be located in the chip area CHA. The test electrodes TE may be located in the upper structure STR2. The test electrodes TE may be located at a level corresponding to the second upper lines UL2. The test electrodes TE may be coupled to the first upper lines UL1 through the upper plugs UP. The test electrodes TE may be coupled to a portion of the first upper lines UL1 included in the circuit structure CS.

Referring to FIG. 2D, the circuit structure CS may include the upper bonding pads UBD and the lower bonding pads LBD that are coupled in series. The upper bonding pads UBD and the lower bonding pads LBD included in the circuit structure CS may be coupled in series to form an electrical path. The upper bonding pads UBD and the lower bonding pads LBD included in the circuit structure CS may form a single electrical path which electrically couples the test electrodes TE.

Among the lower bonding pads LBD included in the circuit structure CS, adjacent lower bonding pads LBD may be electrically coupled to each other through a single third lower line LL3 or through a single first upper line UL1. For example, the adjacent lower bonding pads LBD may be electrically coupled to each other through the lower bonding contact LBC, the third lower line LL3, and another lower bonding contact LBC. Alternatively, the adjacent lower bonding pads LBD may be electrically coupled to each other through the upper bonding pad UBD, the upper bonding contact UBC, the first upper line UL1, another upper bonding contact UBC, and another upper bonding pad UBD.

In addition, among the upper bonding pads UBD included in the circuit structure CS, adjacent upper bonding pads UBD may be electrically coupled to each other through a single third lower line LL3 or through a single first upper line UL1. For example, the adjacent upper bonding pads UBD may be electrically coupled to each other through the upper bonding contact UBC, the first upper line UL1, and another upper bonding contact UBC. Alternatively, the adjacent upper bonding pads UBD may be electrically coupled to each other through the lower bonding pad LBD, the lower bonding contact LBC, the third lower line LL3, another lower bonding contact LBC, and another lower bonding pad LBD.

Among the lower bonding pads LBD included in the circuit structure CS, lower bonding pads LBD that are not adjacent to each other may be electrically coupled to each other through at least one lower bonding pad LBD and at least one upper bonding pad UBD. For example, the lower bonding pads LBD that are not adjacent to each other may be electrically coupled to each other through the upper bonding pad UBD, the upper bonding contact UBC, the first upper line UL1, another upper bonding contact UBC, another upper bonding pad UBD, the lower bonding pad LBD, the lower bonding contact LBC, the third lower line LL3, and another lower bonding contact LBC.

In addition, among the upper bonding pads UBD included in the circuit structure CS, upper bonding pads UBD that are not adjacent to each other may be electrically coupled to each other through at least one lower bonding pad LBD and at least one upper bonding pad UBD. For example, the upper bonding pads UBD that are not adjacent to each other may be electrically coupled to each other through the upper bonding contact UBC, the first upper line UL1, another upper bonding contact UBC, the upper bonding pad UBD, the lower bonding pad LBD, the lower bonding contact LBC, the third lower line LL3, another lower bonding contact LBC, and another lower bonding pad LBD.

In an embodiment, the semiconductor device according to an embodiment of the present disclosure may obtain, using the test electrodes TE, information regarding whether or not the lower structure STR1 and the upper structure STR2 are bonded to each other. For example, the semiconductor device may apply a test voltage to one of the test electrodes TE and may identify whether the test voltage is detected through a remaining test electrode TE. When, in an embodiment, the lower structure STR1 and the upper structure STR2 are bonded to each other, because the upper bonding pads UBD included in the circuit structure CS are in contact with the lower bonding pads LBD, respectively, a test current may flow between the test electrodes TE. When the lower structure STR1 and the upper structure STR2 are not bonded to each other, for example, when a delamination phenomenon occurs, because at least a portion of the upper bonding pads UBD included in the circuit structure CS does not contact the lower bonding pads LBD, a test current might not flow between the test electrodes TE. Accordingly, in an embodiment, the semiconductor device may test whether or not the upper structure STR2 and the lower structure STR1 are bonded to each other by using if the test voltage is detected through the test electrodes TE.

According to an embodiment of the present disclosure, the circuit structure CS might not include any other structures (e.g., cell plugs) except for the bonding pads UBD and LBD and the structure (e.g., the bonding contacts UBC and LBC and the lines LL3 and UL1) for coupling the bonding pads UBD and LBD to each other. For example, the circuit structure CS according to an embodiment of the present disclosure may include only the minimum components to serve as a test circuit. Accordingly, when obtaining information on whether or not bonding is achieved by utilizing the circuit structure CS according to an embodiment of the present disclosure, the influence of other potential defects in the structure STR is mitigated, and therefore the occurrence of a delamination phenomenon may be detected. In addition, a test circuit according to an embodiment of the present disclosure may be used at a late testing stage (e.g., quality testing) among various testing stages included in the manufacturing process of a semiconductor device (e.g., wafer testing, package testing, quality testing). Accordingly, in an embodiment, defects may be detected regardless of whether the defects occur at any stage in the manufacturing process of the semiconductor device. That is, according to an embodiment of the present disclosure, whether or not the bonding pads UBD and LBD are bonded to each other may be detected more easily by improving the structure of the circuit structure CS which serves as a test circuit.

FIGS. 3A to 3E are diagrams illustrating a method of manufacturing the semiconductor device according to the first embodiment of the present disclosure. FIGS. 3A to 3E each correspond to the A-A′ cross-section of FIG. 2A.

Referring to FIG. 3A, the first well area PW and the first activation areas PA may be formed in the substrate SUB. The first well area PW and the first activation areas PA may be formed in the guard area GDA. The first well area PW and the first activation areas PA may surround the chip area CHA. The first well area PW and the first activation areas PA may be formed by an implant process of injecting the first type of impurity into the substrate SUB. For example, the first type of the impurity may be injected into a portion of the substrate SUB to form the first well area PW and the first type of the impurity may be additionally injected into a portion of the first well area PW to form the first activation areas PA.

Referring to FIG. 3B, the first lower plugs LP1, the first lower lines LL1, the second lower plugs LP2, the second lower lines LL2, the third lower plugs LP3, the third lower lines LL3, the lower bonding contacts LBC, and the lower bonding pads LBD may be formed over the substrate SUB. The first lower plugs LP1, the first lower lines LL1, the second lower plugs LP2, the second lower lines LL2, the third lower plugs LP3, the third lower lines LL3, the lower bonding contacts LBC, and the lower bonding pads LBD may be formed in the guard area GDA. The third lower lines LL3, the lower bonding contacts LBC, and the lower bonding pads LBD may be formed in the chip area CHA. The first lower plugs LP1, the first lower lines LL1, the second lower plugs LP2, the second lower lines LL2, the third lower plugs LP3, the third lower lines LL3, the lower bonding contacts LBC, and the lower bonding pads LBD may be surrounded by the lower insulating layer LIL.

For example, after a first insulating layer having a predetermined thickness is formed, a portion of the first insulating layer may be etched. The first lower plugs LP1 may be formed in the etched portion of the first insulating layer. Subsequently, after a second insulating layer covering the first lower plugs LP1 is formed, a portion of the second insulating layer may be etched. Subsequently, the first lower lines LL1 may be formed in the etched portion of the second insulating layer. In the same method as described above, the lower lines and the lower plugs may be formed in the Z direction. The substrate SUB, the lower insulating layer LIL, the first lower plugs LP1, the first lower lines LL1, the second lower plugs LP2, the second lower lines LL2, the third lower plugs LP3, the third lower lines LL3, the lower bonding contacts LBC, and the lower bonding pads LBD may be referred to as the lower structure STR1.

Referring to FIG. 3C, the upper structure STR2 may be formed over a sacrificial substrate SSUB. The upper structure STR2 may include first upper plugs UP1, the first upper lines UL1, the upper bonding contacts UBC, and the upper bonding pads UBD. The first upper plugs UP1, the first upper lines UL1, the upper bonding contacts UBC, and the upper bonding pads UBD may be formed in the guard area GDA. The first upper lines UL1, the upper bonding contacts UBC, and the upper bonding pads UBD may be formed in the chip area CHA. The first upper plugs UP1, the first upper lines UL1, the upper bonding contacts UBC, and the upper bonding pads UBD may be surrounded by a first upper insulating layer UIL1. The upper bonding pads UBD may be exposed to an upper surface of the upper structure STR2. Though not shown in FIG. 3C, the memory cell array may be formed in the chip area CHA.

Referring to FIG. 3D, the upper structure STR2 may be flipped and stacked over the lower structure STR1. The upper bonding pads UBD may be exposed to the lower surface of the upper structure STR2 because the upper structure STR2 is flipped.

Referring to FIG. 3E, the sacrificial substrate SSUB may be removed. For example, the sacrificial substrate SSUB may be selectively etched through an anisotropic dry etching process. Because the sacrificial substrate SSUB is removed, the first upper insulating layer UIL1 and the first upper plug UP1 may be exposed externally.

Subsequently, a second upper insulating layer UIL2 may be formed over the first upper insulating layer UIL1 and a second upper plug UP2 may be formed over the first upper plug UP1. In addition, the second upper lines UL2 may be formed over the second upper plugs UP2. Though not shown in FIG. 3E, when the second upper lines UL2 are formed, the test electrodes TE in FIG. 2C may be formed simultaneously. The words “simultaneous” and “simultaneously” as used herein with respect to processes mean that the processes take place on overlapping intervals of time. For example, if a first process takes place over a first interval of time and a second process takes place simultaneously over a second interval of time, then the first and second intervals at least partially overlap each other such that there exists a time at which the first and second processes are both taking place.

The first well area PW, the first activation areas PA, the first lower plugs LP1, the first lower lines LL1, the second lower plugs LP2, the second lower lines LL2, the third lower plugs LP3, the third lower lines LL3, the lower bonding contacts LBC, the lower bonding pads LBD, the upper bonding pads UBD, the upper bonding contacts UBC, the first upper lines UL1, the first upper plugs UP1, the second upper plugs UP2, and the second upper lines UL2 located in the guard area GDA may form the first and second chip guards GD1 and GD2. The third lower lines LL3, the lower bonding contacts LBC, the lower bonding pads LBD, the upper bonding pads UBD, the upper bonding contacts UBC, and the first upper lines UL1 located in the chip area CHA (e.g., the test circuit area TCR) may form the circuit structure CS. It may be understood as the first upper plug UP1 and the second upper plug UP2 are included in the upper plug UP in FIG. 2B. It may be understood as the first upper insulating layer UIL1 and the second upper insulating layer UIL2 are included in the upper insulating layer UIL in FIG. 2B.

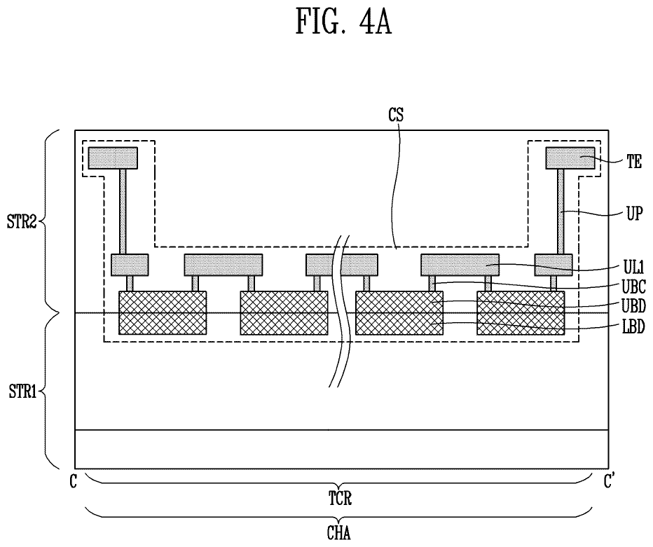

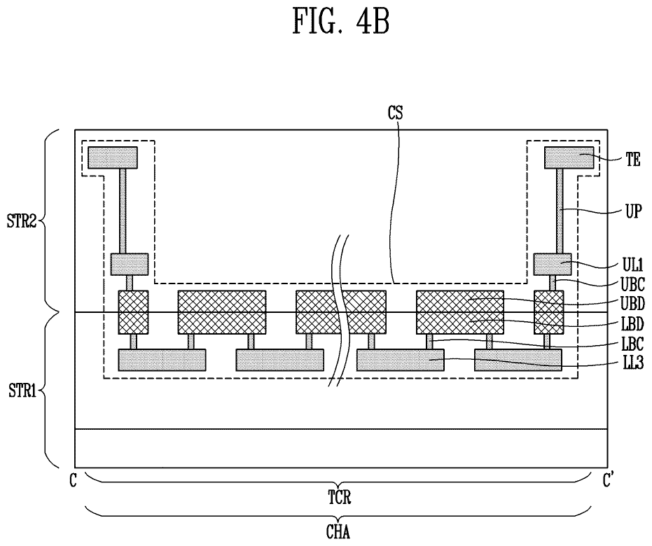

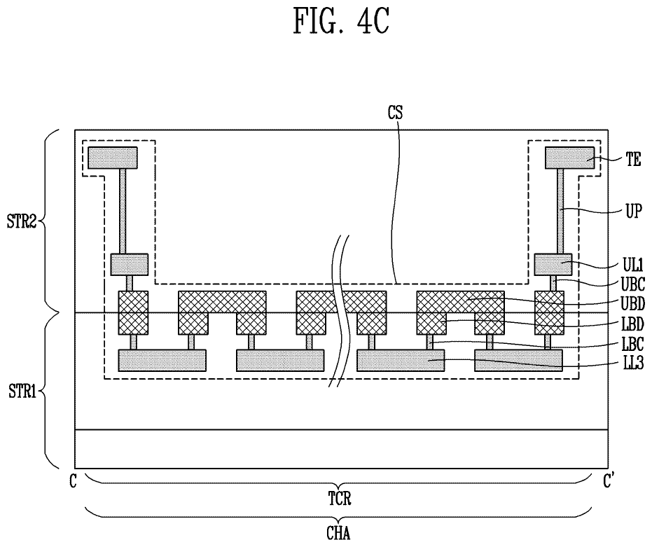

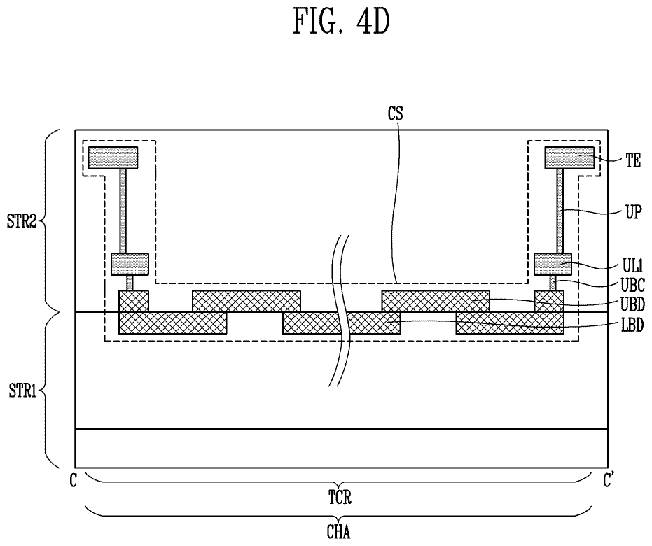

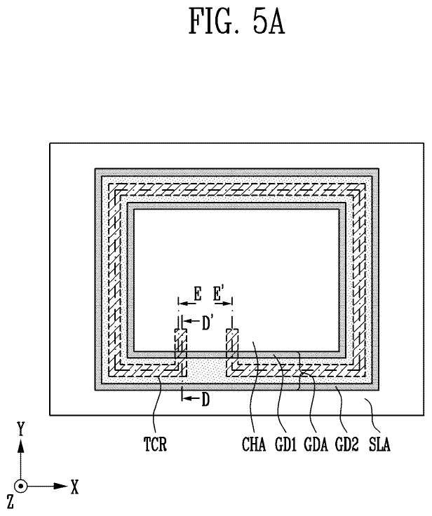

FIGS. 4A to 4D are diagrams illustrating various embodiments related to the first embodiment of the present disclosure. FIGS. 4A to 4D each correspond to the C-C′ cross-section of FIG. 2A. FIGS. 4A to 4D show various embodiments in addition to the first embodiment which is illustrated with respect to FIGS. 2A to 2D. In connection with FIGS. 4A to 4D, a detailed description of the configurations that have already been described with reference to FIGS. 2A to 2D will be omitted or simplified.

Referring to FIGS. 4A to 4D, the circuit structure CS may include the upper bonding pads UBD and the lower bonding pads LBD which are coupled in series. The upper bonding pads UBD and the lower bonding pads LBD included in the circuit structure CS may be coupled in series to form an electrical path. The upper bonding pads UBD and the lower bonding pads LBD included in the circuit structure CS may form a single electrical path which electrically couples the test electrodes TE. In FIGS. 4A to 4D, other chain structures which are different from the chain structure shown in FIG. 2D will be illustrated.

Referring to FIG. 4A, the circuit structure CS may include the lower bonding pads LBD, the upper bonding pads UBD, the upper bonding contacts UBC, and the first upper lines UL1 which are coupled to each other in series. The lower bonding pads LBD, the upper bonding pads UBD, the upper bonding contacts UBC, and the first upper lines UL1 included in the circuit structure CS may be coupled to each other in a chain form. Compared to the structure illustrated in FIG. 2D, the lower bonding contacts LBC and the third lower lines LL3 may be omitted which couple the lower bonding pads LBD.

Among the lower bonding pads LBD included in the circuit structure CS, adjacent lower bonding pads LBD may be electrically coupled to each other through a single first upper line UL1. For example, the adjacent lower bonding pads LBD may be electrically coupled to each other through the upper bonding pad UBD, the upper bonding contact UBC, the first upper line UL1, another upper bonding pad UBD, and another upper bonding contact UBC.

In addition, among the upper bonding pads UBD included in the circuit structure CS, adjacent upper bonding pads UBD may be electrically coupled to each other through a single first upper line UL1. For example, the adjacent upper bonding pads UBD may be electrically coupled to each other through the upper bonding contact UBC, the first upper line UL1, another upper bonding pad UBD, and another upper bonding contact UBC.

Among the lower bonding pads LBD included in the circuit structure CS, lower bonding pads LBD that are not adjacent to each other may be electrically coupled to each other through at least one lower bonding pad LBD and at least one upper bonding pad UBD. In addition, among the upper bonding pads UBD included in the circuit structure CS, upper bonding pads UBD that are not adjacent to each other may be electrically coupled to each other through at least one lower bonding pad LBD and at least one upper bonding pad UBD.

Referring to FIG. 4B, the circuit structure CS may include the third lower lines LL3, the lower bonding contacts LBC, the lower bonding pads LBD, and the upper bonding pads UBD which are coupled in series. The third lower lines LL3, the lower bonding contacts LBC, the lower bonding pads LBD, and the upper bonding pads UBD included in the circuit structure CS may be coupled to each other in a chain form. Compared to the structure illustrated in FIG. 2D, the upper bonding contacts UBC and the first upper lines UL1 may be omitted which couple the upper bonding pads UBD to each other.

Among the lower bonding pads LBD included in the circuit structure CS, adjacent lower bonding pads LBD may be electrically coupled to each other through a single third lower line LL3. For example, the adjacent lower bonding pads LBD may be electrically coupled to each other through the lower bonding contact LBC, the third lower line LL3, and another lower bonding contact LBC.

In addition, among the upper bonding pads UBD included in the circuit structure CS, adjacent upper bonding pads UBD may be electrically coupled to each other through a single third lower line LL3. For example, the adjacent upper bonding pads UBD may be coupled to each other through the lower bonding pad LBD, the lower bonding contact LBC, the third lower line LL3, another lower bonding contact LBC, and another lower bonding pad LBD.

Among the lower bonding pads LBD included in the circuit structure CS, lower bonding pads LBD that are not adjacent to each other may be electrically coupled to each other through at least one lower pad bonding LBD and at least one upper bonding pad UBD. In addition, among the upper bonding pads UBD included in the circuit structure CS, upper bonding pads UBD that are not adjacent to each other may be electrically coupled to each other through at least one lower bonding pad LBD and at least one upper bonding pad UBD.

Referring to FIG. 4C, at least a portion of each of the upper bonding pads UBD might not overlap the lower bonding pads LBD. The lower bonding pads LBD may have a smaller length in the horizontal direction than the upper bonding pads UBD. Two lower bonding pads LBD may contact one of the upper bonding pads UBD. The upper bonding pad UBD may electrically couple two lower bonding pads LBD.

Among the lower bonding pads LBD included in the circuit structure CS, adjacent lower bonding pads LBD may be electrically coupled to each other through a single third lower line LL3 or through a single upper bonding pad UBD. For example, the adjacent lower bonding pads LBD may be electrically coupled to each other through the lower bonding contact LBC, the third lower line LL3, and another lower bonding contact LBC. Alternatively, the adjacent lower bonding pads LBD may be electrically coupled to each other through one of the upper bonding pads UBD.

In addition, among the upper bonding pads UBD included in the circuit structure CS, adjacent upper bonding pads UBD may be electrically coupled to each other through a single third lower line LL3. For example, the adjacent upper bonding pads UBD may be electrically coupled to each other through the lower bonding pad LBD, the lower bonding contact LBC, the third lower line LL3, another lower bonding contact LBC, and another lower bonding pad LBD.

Among the lower bonding pads LBD included in the circuit structure CS, lower bonding pads LBD that are not adjacent to each other may be electrically coupled to each other through at least one lower bonding pad LBD and at least one upper bonding pad UBD. For example, the lower bonding pads LBD that are not adjacent to each other may be electrically coupled to each other through the upper bonding pad UBD, the lower bonding pad LBD, the lower bonding contact LBC, the third lower line LL3, and another lower bonding contact LBC.

In addition, among the upper bonding pads UBD included in the circuit structure CS, upper bonding pads UBD that are not adjacent to each other may be electrically coupled to each other through at least one lower bonding pad LBD and at least one upper bonding pad UBD. For example, the upper bonding pads UBD that are not adjacent to each other may be electrically coupled to each other through the lower bonding pad LBD, the lower bonding contact LBC, the third lower line LL3, another lower bonding contact LBC, another lower bonding pad LBD, the upper bonding pad UBD, another lower bonding pad LBD, another lower bonding contact LBC, another third lower line LL3, another lower bonding contact LBC, and another lower bonding pad LBD.

Unlike the embodiment shown in FIG. 4C, each of the lower bonding pads LBD may have a greater length in the horizontal direction than each of the upper bonding pads UBD. For example, the upper bonding contacts UBC and the first upper lines UL1 may form a chain structure in the circuit structure CS in place of the lower bonding contacts LBC and the third lower lines LL3.

Referring to FIG. 4D, the circuit structure CS may include the upper bonding pads UBD and the lower bonding pads LBD which are coupled in a chain structure. A portion of each of the upper bonding pads UBD might not overlap the lower bonding pads LBD. In addition, a portion of each of the lower bonding pads LBD might not overlap the upper bonding pads UBD.

Among the lower bonding pads LBD included in the circuit structure CS, adjacent lower bonding pads LBD may be electrically coupled to each other through a single upper bonding pad UBD. In addition, among the upper bonding pads UBD included in the circuit structure CS, adjacent upper bonding pads UBD may be electrically coupled to each other through a single lower bonding pad LBD.

Among the lower bonding pads LBD included in the circuit structure CS, lower bonding pads LBD that are not adjacent to each other may be electrically coupled to each other through at least one lower bonding pad LBD and at least one upper bonding pad UBD. For example, the lower bonding pads LBD that are not adjacent to each other may be electrically coupled to each other through two or more upper bonding pads UBD and one or more lower bonding pads LBD.

In addition, among the upper bonding pads UBD included in the circuit structure CS, upper bonding pads UBD that are not adjacent to each other may be electrically coupled to each other through at least one lower bonding pad LBD and at least one upper bonding pad UBD. For example, the upper bonding pads UBD that are not adjacent to each other may be electrically coupled to each other through two or more lower bonding pads LBD and one or more upper bonding pads UBD.

In addition to the structures of the circuit structure CS illustrated with respect to FIGS. 4A to 4D, various embodiments of which the bonding pads UBD and LBD are coupled in series may be included within the scope of the present disclosure.

FIGS. 5A to 5C are diagrams illustrating a structure of a semiconductor device according to second embodiments of the present disclosure. FIG. 5A is a plan view of a layout of the semiconductor device according to the second embodiments of the present disclosure. FIG. 5B shows a cross-section taken along line D-D′ of FIG. 5A. FIG. 5C shows a cross-section taken along line E-E′ of FIG. 5A.

FIGS. 5A to 5C show the second embodiment different from the first embodiment which is illustrated with respect to FIGS. 2A to 2D. In connection with FIGS. 5A to 5C, a detailed description of the configurations that have already been described with reference to FIGS. 2A to 2D will be omitted or simplified.

Referring to FIG. 5A, the first and second chip guards GD1 and GD2 may surround the chip area CHA. The first and second chip guards GD1 and GD2 may be spaced apart from each other. For example, the first chip guard GD1 may surround the chip area CHA, and the second chip guard GD2 may surround the chip area CHA and the first chip guard GD1.

The test circuit area TCR may be located in the chip area CHA. At least a portion of the test circuit area TCR may be located between the first chip guard GD1 and the second chip guard GD2. The test circuit area TCR may extend in a direction in which the first and second chip guards GD1 and GD2 are extended.

The test circuit area TCR may extend into the chip area CHA. At least a portion of the test circuit area TCR may be located in the chip area CHA. The portion of the test circuit area TCR may overlap the first chip guard GD1.

Referring to FIGS. 5A and 5B, the circuit structure CS may include the bonding pads UBD and LBD located between the first and second chip guards GD1 and GD2. A portion of the bonding pads UBD and LBD included in the circuit structure CS may be disposed in the guard area GDA. In the guard area GDA, the bonding pads UBD and LBD included in the circuit structure CS may be disposed along a space between the first and second chip guards GD1 and GD2. For example, each of the upper bonding pads UBD and the lower bonding pads LBD included in the circuit structure CS may be disposed along the direction in which the first and second chip guards GD1 and GD2 are extended.

The circuit structure CS may include the test electrodes TE. The test electrodes TE may be located in the chip area CHA. For example, the test electrodes TE may be disposed in the chip area CHA so that the circuit structure CS to be served as a test circuit.

The circuit structure CS may include an electrical path which electrically couples the bonding pads UBD and LBD in the guard area GDA to the test electrodes TE in the chip area CHA. The circuit structure CS may include second activation areas NA, second well areas NW, and third well areas DW. The second well area NW and the second activation area NA may be areas of the substrate SUB into which a second type of impurity is injected. The amount of the impurity included in the second activation area NA may be greater than the amount of the impurity included in the second well area NW. The second type of impurity may include an element of group 15. For example, the second type of impurity may include phosphorus (P). The third well area DW may be an area where the second type of impurity is injected into the substrate SUB. The third well area DW may be formed to be deeper than the first well area PW. For example, as shown in FIG. 5B, the third well area DW may be formed at a greater depth than the first well area PW in the opposite direction of Z. In an embodiment, the circuit structure CS includes second activation areas NA, second well areas NW, and a third well area DW having a greater depth than the first well area PW in the substrate SUB. For example, the circuit structure CS includes second activation areas NA, second well areas NW, and a third well area DW having a greater depth than the first well area PW in the opposite direction of Z. Accordingly, at a lower portion of the first well area PW included in the first chip guard GD1, the second well areas NW may be electrically coupled to each other through the third well area DW. In the guard area GDA, the upper bonding pads UBD and the lower bonding pads LBD included in the circuit structure CS may be electrically coupled to the test electrodes TE through the third well area DW.

The third well area DW may extend from the guard area GDA into the chip area CHA. A portion of the third well area DW may be located in the guard area GDA. Another portion of the third well area DW may be located in the chip area CHA. The third well area DW may be located at a lower portion of the first chip guard GD1. Accordingly, the circuit structure CS may overlap the first chip guard GD1.

Isolation structures IS may be respectively located between the first well areas PW and the second well areas NW. The isolation structure IS may include an insulating material which is filled in the substrate SUB. The first well areas PW and the second well areas NW may be insulated from each other by the isolation structure IS.

In the guard area GDA, the circuit structure CS may include the lower bonding contact LBC, the third lower line LL3, the third lower plug LP3, the second lower line LL2, the second lower plug LP2, the first lower line LL1, and the first lower plug LP1 which couple the lower bonding pad LBD to the second activation area NA. In addition, in the chip area CHA, the circuit structure CS may include the first lower plug LP1, the first lower line LL1, the second lower plug LP2, the second lower line LL2, the third lower plug LP3, the third lower line LL3, the lower bonding contact LBC, the lower bonding pad LBD, the upper bonding pad UBD, the upper bonding contact UBC, the first upper line UL1, and the upper plug UP which couple the second activation area NA to the test electrode TE.

Referring to FIG. 5C, the circuit structure CS may include the bonding pads UBD and LBD which are coupled in series in the guard area GDA. The circuit structure CS may include the bonding pads UBD and LBD which are coupled in series between the first and second chip guards GD1 and GD2. In the guard area GDA, the circuit structure CS may include the first upper lines UL1, the upper bonding contacts UBC, the upper bonding pads UBD, the lower bonding pads LBD, the lower bonding contacts LBC, and the third lower lines LL3 which are coupled in series. In the guard area GDA, the first upper lines UL1, the upper bonding contacts UBC, the upper bonding pads UBD, the lower bonding pads LBD, the lower bonding contacts LBC, and the third lower lines LL3 may be consecutively coupled to each other. The connection relationship between the first upper lines UL1, the upper bonding contacts UBC, the upper bonding pads UBD, the lower bonding pads LBD, the lower bonding contacts LBC, and the third lower lines LL3 included in the circuit structure CS, which is described with reference to FIG. 2D, may be similarly applied to FIG. 5C with the exception that they are located in the guard area GDA.

According to the second embodiments of the present disclosure, the timing for detecting whether or not the bonding pads UBD and LBD are bonded to each other may be set differently by disposing the portion of the circuit structure CS between the first and second chip guards GD1 and GD2. For example, among various testing stages included in the manufacturing process of a semiconductor device, the occurrence of a delamination phenomenon may be detected not only at a late testing stage but also at an early testing stage.

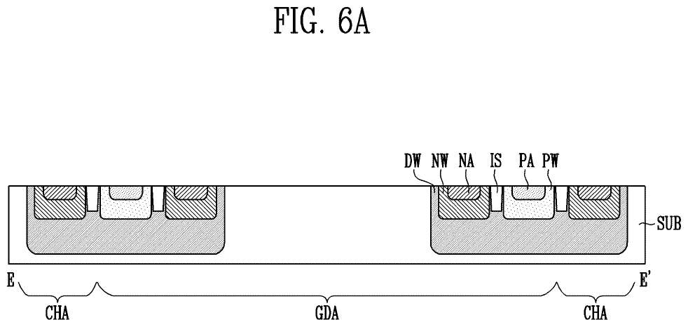

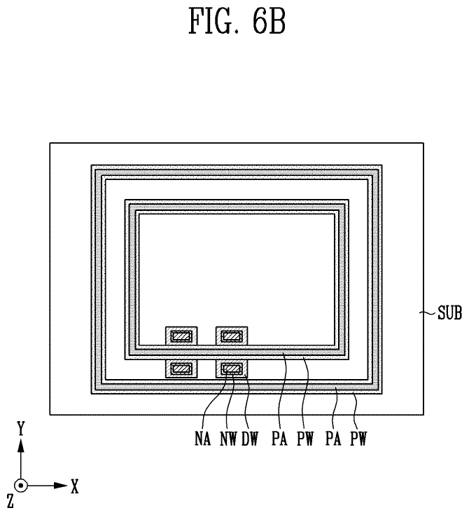

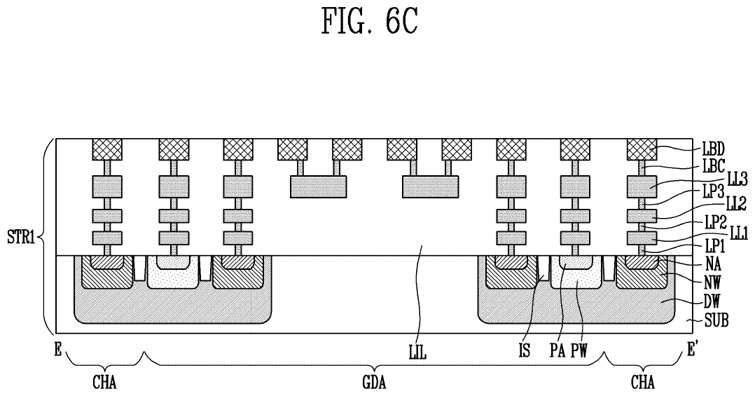

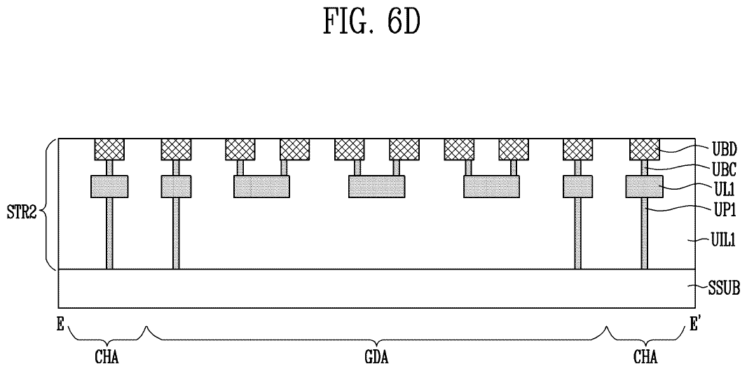

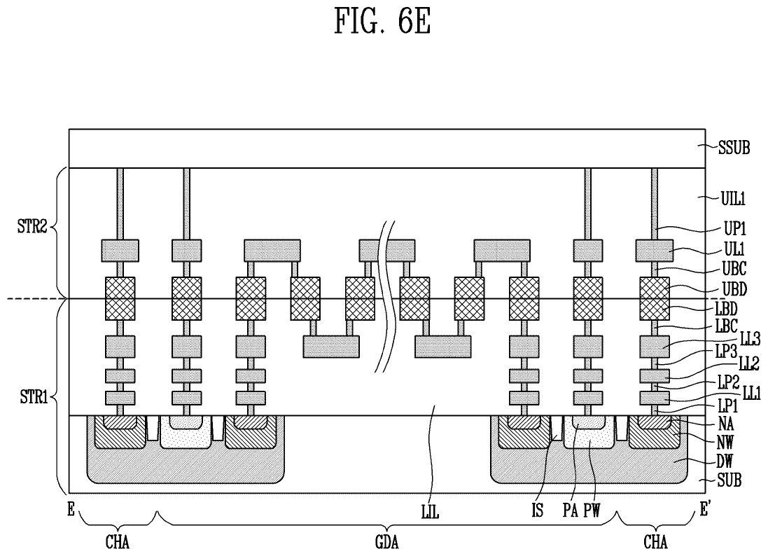

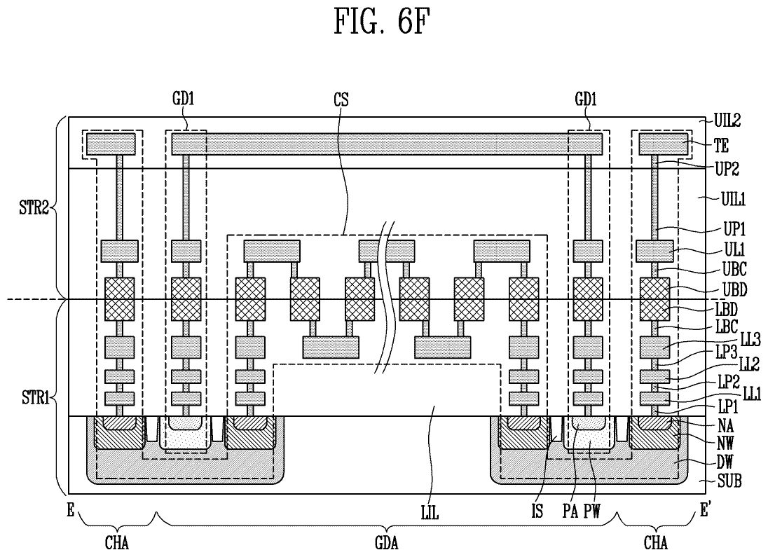

FIGS. 6A to 6F are diagrams illustrating a method of manufacturing the semiconductor device according to the second embodiments of the present disclosure. FIG. 6A, and FIGS. 6C to 6F each correspond to the E-E′ cross-section of FIG. 5A. FIG. 6B shows a cross-section of FIG. 6A.

In connection with FIGS. 6A to 6F, a detailed description of the configurations that have already been described with reference to FIGS. 3A to 3E will be omitted or simplified.

Referring to FIGS. 6A and 6B, the first well areas PW, the first activation areas PA, the second well areas NW, the second activation areas NA, and the third well areas DW may be formed in the substrate SUB. The first well areas PW and the first activation areas PA may be formed in the guard area GDA. The first well areas PW and the first activation areas PA may surround the chip area CHA. A portion of the second well areas NW may be formed in the guard area GDA and another portion of the second well areas NW may be formed in the chip area CHA. Each of the second activation areas NA may overlap each of the second well areas NW. Each of the third well areas DW may extend from the guard area GDA towards the chip area CHA.

The first well area PW and the first activation areas PA may be formed by the implant process of injecting the first type of impurity into the substrate SUB. For example, the first type of impurity may be injected into the portion of the substrate SUB to form the first well area PW and the first type of impurity may be additionally injected into the portion of the first well area PW to form the first activation areas PA.

The second well area NW and the second activation areas NA may be formed by an implant process of injecting the second type of impurity into the substrate SUB. For example, the second type of impurity may be injected into the portion of the substrate SUB to form the second well area NW and the second type of impurity may be additionally injected into a portion of the second well area NW to form the second activation areas NA.

The third well area DW may be formed by the implant process of injecting the second type of impurity into the substrate SUB. The third well area DW may be formed to be deeper than the first well areas PW and the second well areas NW. In the implant process of forming the third well regions DW, the impurity may be injected into the third well regions DW at a higher voltage than in the implant process of forming the first well areas PW and the second well areas NW.

The order of formation of the first well areas PW, the first activation areas PA, the second well areas NW, and the third well areas DW may vary. For example, the first and second well areas PW and NW may be formed after the third well areas DW are formed. In another example, the third well areas DW may be formed after the first and second well areas PW and NW and the first and second activation areas PA and NA are formed.

The isolation structures IS may be formed in the substrate SUB. The isolation structures IS may separate the first well areas PW and the second well areas NW from each other. For example, the isolation structures IS may be formed by filling an insulating material into a space where a portion of the substrate SUB is removed. The isolation structures IS may be formed through various processes in addition to the aforementioned process. The isolation structures IS may be formed before or after the first to third well areas PW, NW, and DW and the first and second activation areas PA and NA are formed.

In FIG. 6B, the first well areas PW are illustrated as being divided from each other, but the scope of the present disclosure is not limited thereto. For example, as shown in FIG. 3A, the first well areas PW may extend from each other. In other words, the first well area PW included in the first chip guard GD1 and the first well area PW included in the second chip guard GD2 may be separated from or coupled to each other.

Referring to FIG. 6C, the first lower plugs LP1, the first lower lines LL1, the second lower plugs LP2, the second lower lines LL2, the third lower plugs LP3, the third lower lines LL3, the lower bonding contacts LBC, and the lower bonding pads LBD may be formed over the substrate SUB. The first lower plugs LP1, the first lower lines LL1, the second lower plugs LP2, the second lower lines LL2, the third lower plugs LP3, the third lower lines LL3, the lower bonding contacts LBC, and the lower bonding pads LBD may be formed over the first activation areas PA and the second activation areas NA. The third lower lines LL3, the lower bonding contacts LBC, and the lower bonding pads LBD may be formed in the guard area GDA. The first lower plugs LP1, the first lower lines LL1, the second lower plugs LP2, the second lower lines LL2, the third lower plugs LP3, the third lower lines LL3, the lower bonding contacts LBC, and the lower bonding pads LBD may be surrounded by the lower insulating layer LIL.

Referring to FIG. 6D, the upper structure STR2 may be formed over the sacrificial substrate SSUB. The upper structure STR2 may include the first upper plugs UP1, the first upper lines UL1, the upper bonding contacts UBC, and the upper bonding pads UBD. The first upper plugs UP1, the first upper lines UL1, the upper bonding contacts UBC, and the upper bonding pads UBD may be surrounded by the first upper insulating layer UIL1. The upper bonding pads UBD may be exposed to the upper surface of the upper structure STR2. Though not shown in FIG. 6D, the memory cell array may be formed in the chip area CHA.

Referring to FIG. 6E, the upper structure STR2 may be flipped and stacked over the lower structure STR1. The upper bonding pads UBD may be exposed to the lower surface of the upper structure STR2 because the upper structure STR2 is flipped.

Referring to FIG. 6F, the sacrificial substrate SSUB may be removed. Subsequently, the second upper insulating layer UIL2 may be formed over the first upper insulating layer UIL1, and the second upper plug UP2 may be formed over the first upper plug UP1. In addition, the second upper lines UL2 and the test electrodes TE may be formed over the second upper plugs UP2.

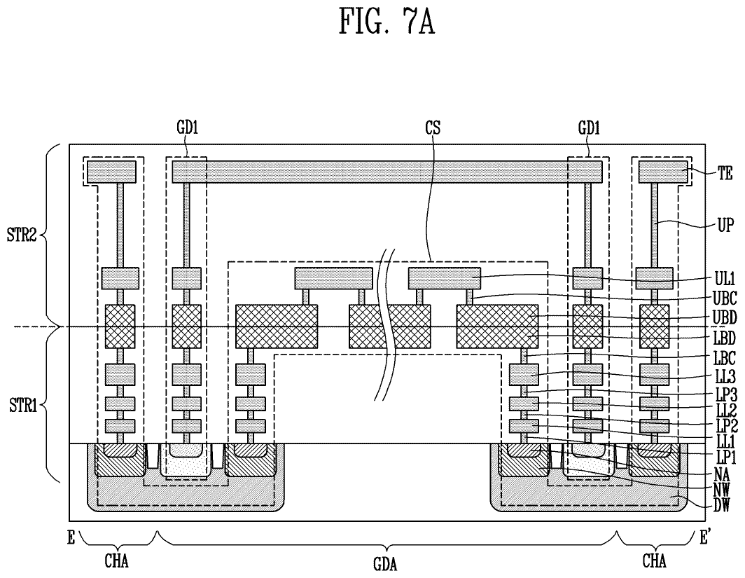

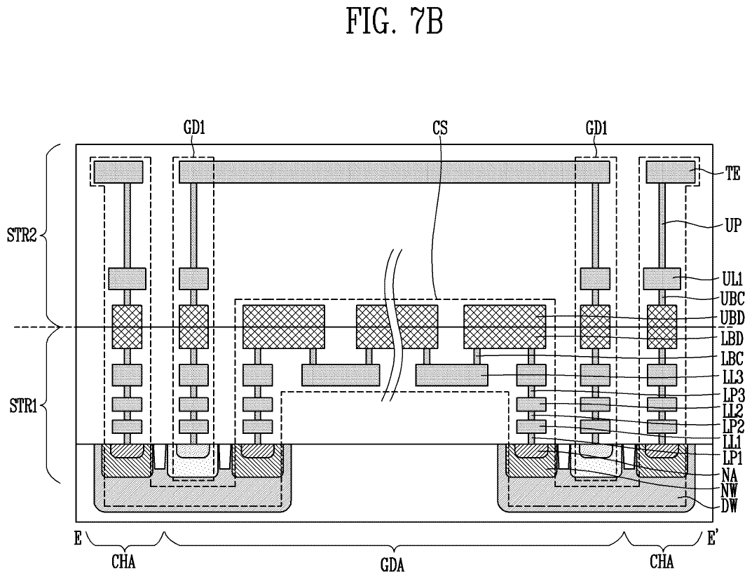

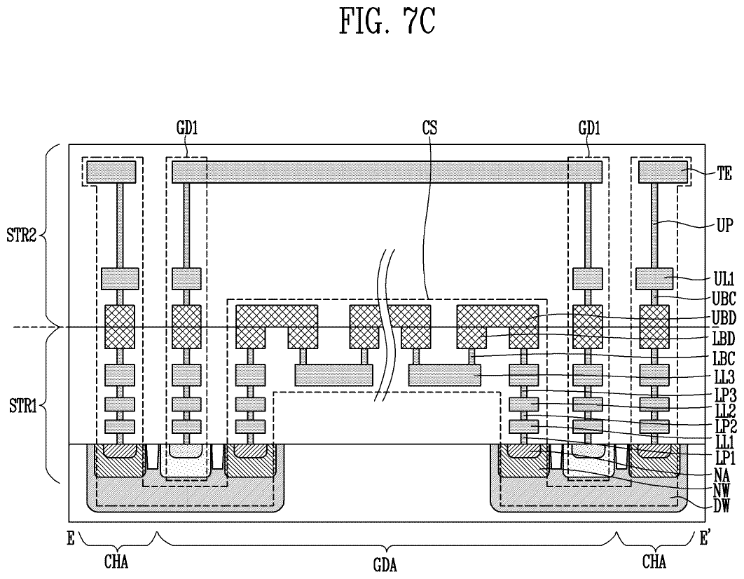

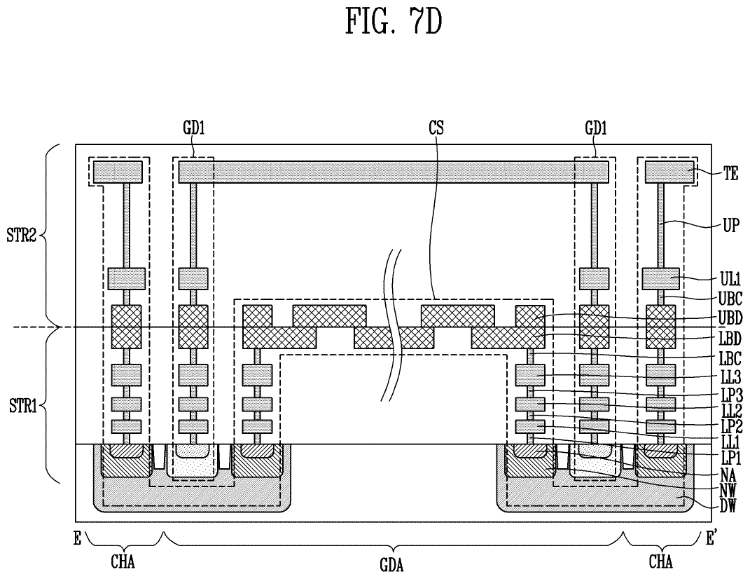

FIGS. 7A to 7D are diagrams illustrating various embodiments related to the second embodiment of the present disclosure. FIGS. 7A to 7D each correspond to the E-E′ cross-section of FIG. 5A. FIGS. 7A to 7D show various embodiments in addition to the second embodiments which is illustrated with respect to FIGS. 5A to 5C. In connection with FIGS. 7A to 7D, a detailed description of the configurations that have already been described with reference to FIGS. 5A to 5C will be omitted or simplified.

Referring to FIGS. 7A to 7D, the circuit structure CS may include the upper bonding pads UBD and the lower bonding pads LBD which are coupled in series. The upper bonding pads UBD and the lower bonding pads LBD included in the circuit structure CS may be coupled in series to form an electrical path. The upper bonding pads UBD and the lower bonding pads LBD included in the circuit structure CS may form a single electrical path which electrically couples the test electrodes TE. FIGS. 7A to 7D show other chain structure that is different from the chain structure shown in FIG. 5C.

Referring to FIG. 7A, the circuit structure CS may include the lower bonding pads LBD, the upper bonding pads UBD, the upper bonding contacts UBC, and the first upper lines UL1 which are coupled in series. The lower bonding pads LBD, the upper bonding pads UBD, the upper bonding contacts UBC, and the first upper lines UL1 include in the circuit structure CS may be coupled to each other in a chain form. Compared to the structure illustrated in FIG. 4A, except for that the bonding pads UBD and LBD are located in the guard area GDA, not in the chip area CHA, the bonding pads UBD and LBD may have the same chain structure. Accordingly, the specific connection structure of the bonding pads UBD and LBD illustrated in FIG. 4A may also be applied to FIG. 7A.

Referring to FIG. 7D, the circuit structure CS may include the third lower lines LL3, the lower bonding contacts LBC, the lower bonding pads LBD, and the upper bonding pads UBD which are coupled in series. The third lower lines LL3, the lower bonding contacts LBC, the lower bonding pads LBD, and the upper bonding pads UBD included in the circuit structure CS may be coupled to each other in a chain form. Compared to the structure illustrated in FIG. 4B, except for that the bonding pads UBD and LBD are located in the guard area GDA, not in the chip area CHA, the bonding pads UBD and LBD may have the same chain structure. Accordingly, the specific connection structure of the bonding pads UBD and LBD illustrated in FIG. 4B may also be applied to FIG. 7B.

Referring to FIG. 7C, at least a portion of each of the upper bonding pads UBD might not overlap the lower bonding pads LBD. Each of the lower bonding pads LBD may have a smaller length in the horizontal direction than each of the upper bonding pads UBD. Two lower bonding pads LBD may contact one of the upper bonding pads UBD. The upper bonding pad UBD may electrically couple two lower bonding pads LBD. Compared to the structure illustrated in FIG. 4C, except for that the bonding pads UBD and LBD are located in the guard area GDA, not in the chip area CHA, the bonding pads UBD and LBD may have the same chain structure. Accordingly, the specific connection structure of the bonding pads UBD and LBD illustrated in FIG. 4C may also be applied to FIG. 7C.

Referring to FIG. 7D, the circuit structure CS may include the upper bonding pads UBD and the lower bonding pads LBD coupled in a chain structure. At least a portion of each of the upper bonding pads UBD might not overlap the lower bonding pads LBD. In addition, at least a portion of each of the lower bonding pads LBD might not overlap the upper bonding pads UBD. Compared to the structure illustrated in FIG. 4D, except for that the bonding pads UBD and LBD are located in the guard area GDA, not in the chip area CHA, the bonding pads UBD and LBD may have the same chain structure. Accordingly, the specific connection structure of the bonding pads UBD and LBD illustrated in FIG. 4D may also be applied to FIG. 7D.

In addition to the structures of the circuit structure CS illustrated with respect to FIGS. 7A to 7D, various embodiments of which the bonding pads UBD and LBD are coupled in series may be included within the scope of the present disclosure.

FIGS. 8A to 8D are diagrams illustrating a memory device including the circuit structure CS according to an embodiment of the present disclosure.

FIGS. 8A and 8B show the memory device including the circuit structure CS according to the first embodiments of the present disclosure. FIGS. 8C and 8D show the memory device including the circuit structure CS according to the second embodiments of the present disclosure.

In connection with FIGS. 8A to 8D, a detailed description of the configurations that have already been described with reference to FIGS. 2A to 7D will be omitted or simplified.

Referring to FIGS. 8A and 8C, the memory cell array may be formed in the chip area CHA. Cell plugs CPL, contacts CT, and peripheral circuit contact PCT may be located in the chip area CHA. FIGS. 8A and 8C merely illustrate a portion of the memory cell array included in the memory device. Accordingly, the number, location, and shape of the memory cell array do not limit the scope of the present disclosure and are not limited to those shown in FIGS. 8A and 8C. In an embodiment, a memory cell array may include a stack structure, conductive layers CD, interlayer insulating layers IIL, cell plugs CPL, contacts CT, and a source layer SL. For example, a memory cell array may include a stack structure including conductive layers CD and interlayer insulating layers IIL alternately stacked, cell plugs CPL penetrating the stack structure, contacts CT coupled to the conductive layers CD, respectively, and a source layer SL contacting the cell plugs CPL over the stack structure.

FIG. 8B shows a cross-section taken along line F-F′ of FIG. 8A. FIG. 8D shows a cross-section taken along line G-G′ of FIG. 8C.

Referring to FIGS. 8B and 8D, the upper structure STR2 may include conductive layers CD and interlayer insulating layers IIL which are alternately stacked in the chip area CHA. The conductive layers CD and the interlayer insulating layers IIL may be alternately disposed in the Z direction. The conductive layers CD and the interlayer insulating layers IIL may have a stepped structure. As the conductive layer CD is located at an upper portion among the conductive layers CD, the conductive layer CD may have a greater length in the X direction. The upper structure STR2 may include a source layer SL which covers the conductive layers CD and the interlayer insulating layers IIL. The source layer SL may be located in the Z direction with respect to the conductive layers CD and the interlayer insulating layers IIL. The upper structure STR2 may include the cell plugs CPL which penetrate the conductive layers CD and the interlayer insulating layers IIL. Each of the cell plugs CPL may extend in the Z direction. The cell plugs CPL may extend into the source layer SL. Each of the cell plugs CPL may have a width which becomes narrower towards the top. The upper structure STR2 may have the contacts CT respectively coupled to the conductive layers CD. The contacts CT may respectively contact the conductive layers CD which form the stepped structure. The upper structure STR2 may include the peripheral circuit contact PCT. The peripheral circuit contact PCT may be spaced apart from the conductive layers CD.

The cell plugs CPL may be coupled to the substrate SUB through cell contacts CC, the first upper plug UP1, the first upper line UL1, the upper bonding contact UBC, the upper bonding pad UBD, the lower bonding pad LBD, the lower bonding contact LBC, the third lower line LL3, the third lower plug LP3, the second lower line LL2, the second lower plug LP2, the first lower line LL1, and the first lower plug LP1. Though not shown in FIGS. 8B and 8D, the cell plugs CPL may be electrically coupled to transistors which are formed in and over the substrate SUB. The contacts CT may be coupled to the upper bonding pad UBD through the first upper line UL1 and the upper bonding contact UBC. The contacts CT may be electrically coupled to the lower structure STR1 by the upper bonding pad UBD and the lower bonding pad LBD. Though not shown in FIGS. 8B and 8D either, the contacts CT may be electrically coupled to a control circuit (e.g., pass transistors) formed in the lower structure STR1. The source layer SL may be coupled to the second upper line UL2 through the second upper plug UP2. The peripheral circuit contact PCT may be coupled to the second upper line UL2. The peripheral circuit contact PCT may be coupled to the substrate SUB through the first upper line UL1, the upper bonding contact UBC, the upper bonding pad UBD, the lower bonding pad LBD, the lower bonding contact LBC, the third lower line LL3, the third lower plug LP3, the second lower line LL2, the second lower plug LP2, the first lower line LL1, and the first lower plug LP1. The peripheral circuit contact PCT may be coupled to a peripheral circuit included in the lower structure STR1. For example, though not shown, the peripheral circuit contact PCT may be electrically coupled to the transistor which is formed in and over the substrate SUB.

The circuit structure CS according to the first and second embodiments of the present disclosure may be disposed to surround the components necessary for the operation of the memory device, such as the cell plugs CPL, the contacts CT, the peripheral circuit contact PCT, a stack structure of the conductive layers CD and the interlayer insulating layers IIL, and the source layer SL. In addition, the test electrodes TE of the circuit structure CS may be located farther in the Z direction than the source layer SL, the conductive layers CD, the interlayer insulating layers IIL, the cell plugs CPL, and the contacts CT. The upper bonding pads UBD and the lower bonding pads LBD included in the circuit structure CS may be located farther in an opposite direction to the Z direction than the source layer SL, the conductive layers CD, the interlayer insulating layers IIL, the cell plugs CPL, and the contacts CT.

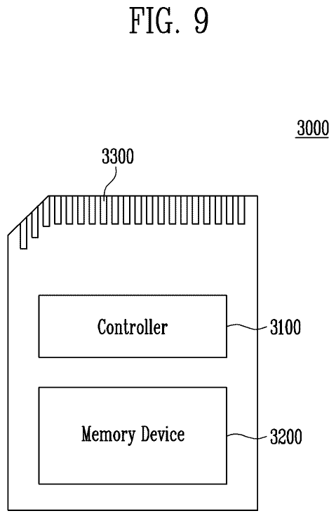

FIG. 9 is a diagram illustrating a memory card system 3000 to which a memory device according to an embodiment of the present disclosure is applied.

Referring to FIG. 9, the memory card system 3000 may include a controller 3100, a memory device 3200, and a connector 3300.

The controller 3100 may be coupled to the memory device 3200. The controller 3100 may be configured to access the memory device 3200. For example, the controller 3100 may be configured to control a program operation, a read operation, or an erase operation of the memory device 3200, or control a background operation. The controller 3100 may be configured to provide an interface between the memory device 3200 and a host. The controller 3100 may be configured to drive firmware for controlling the memory device 3200. For example, the controller 3100 may include components such as a Random Access Memory (RAM), a processing unit, a host interface, a memory interface, and an error corrector.

The controller 3100 may communicate with an external device through the connector 3300. The controller 3100 may communicate with the external device (e.g., the host) according to a specific communication protocol. For example, the controller 3100 may be configured to communicate with the external device through at least one of various communication protocols such as Universal Serial Bus (USB), Multi-Media Card (MMC), embedded MMC (eMMC), Peripheral Component Interconnect (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), Integrated Drive Electronics (IDE), Firewire, Universal Flash Storage (UFS), Wi-Fi, Bluetooth, and NVMe protocols. For example, the connector 3300 may be defined by at least one of the above-described various communication protocols.

The memory device 3200 may include a memory cell array including a plurality of memory cells.

The controller 3100 and the memory device 3200 may be integrated into a single semiconductor device to constitute a memory card. For example, the controller 3100 and the memory device 3200 may be integrated into a single semiconductor device to constitute a memory card such as a personal computer (PC) card in the form of a Personal Computer Memory Card International Association (PCMCIA) card, a Compact Flash (CF) card, a Smart Media Card (SM and SMC), a memory stick, a Multi-Media Card (MMC, RS-MMC, MMCmicro, or eMMC), a Secure Digital (SD) card (SD, miniSD, microSD, or SDHC), and a Universal Flash Storage (UFS).

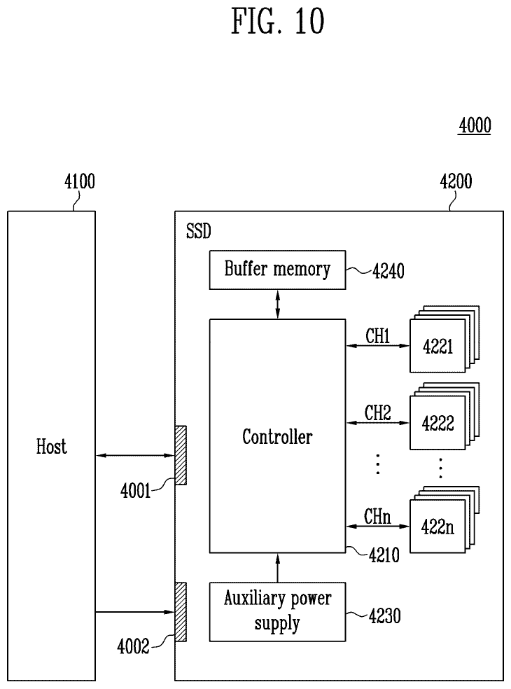

FIG. 10 is a diagram illustrating a solid state drive (SSD) system 4000 to which a memory device according to an embodiment of the present disclosure is applied.

Referring to FIG. 10, the SSD system 4000 may include a host 4100 and an SSD 4200. The SSD 4200 may exchange a signal with the host 4100 through a signal connector 4001, and may receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to signals received from the host 4100. For example, the signals may be based on an interface between the host 4100 and the SSD 4200. For example, the signals may be defined by at least one of interfaces such as Universal Serial Bus (USB), Multi-Media Card (MMC), embedded MMC (eMMC), Peripheral Component Interconnect (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), Integrated Drive Electronics (IDE), Firewire, Universal Flash Storage (UFS), Wi-Fi, Bluetooth, and NVMe interfaces.

The plurality of memory devices 4221 to 422n may include a plurality of memory cells configured to store data. The plurality of memory devices 4221 to 422n may communicate with the controller 4210 through channels CH1 to CHn.

The auxiliary power supply 4230 may be coupled to the host 4100 through a power connector 4002. The auxiliary power supply 4230 may receive and be charged with a power voltage from the host 4100. When the supply of power from the host 4100 is not smooth, the auxiliary power supply 4230 may provide a power voltage of the SSD 4200. For example, the auxiliary power supply 4230 may be located inside or outside the SSD 4200. For example, the auxiliary power supply 4230 may be located on a main board and provide auxiliary power to the SSD 4200.

The buffer memory 4240 may serve as a buffer memory of the SSD 4200. For example, the buffer memory 4240 may store data received from the host 4100 or data received from the plurality of memory devices 4221 to 422n, or may store metadata (e.g., mapping tables) of the memory devices 4221 to 422n. The buffer memory 4240 may include volatile memories such as DRAM, SDRAM, DDR SDRAM, and LPDDR SDRAM, or non-volatile memories such as FRAM, ReRAM, STT-MRAM, and PRAM.

According to embodiments of the present disclosure, it may be detected more easily whether or not bonding pads are bonded to each other by improving the structure and layout of a test circuit.

What is claimed is:

1. A semiconductor device, comprising:
a guard area;
a chip area surrounded by the guard area; and
a circuit structure including bonding pads coupled in series in the chip area.

2. The semiconductor device of claim 1, further comprising a memory cell array in the chip area,
wherein the circuit structure is disposed between the memory cell array and the guard area.

3. The semiconductor device of claim 1, wherein the chip area includes a first area including a center of the chip area and a second area surrounding the first area, and
wherein the circuit structure is disposed in the second area of the chip area.

4. The semiconductor device of claim 1, wherein the circuit structure extends along an interface between the chip area and the guard area.

5. The semiconductor device of claim 1, wherein the chip area has substantially a rectangular shape, and
wherein the circuit structure has a shape which corresponds to a portion of the substantially rectangular shape.

6. The semiconductor device of claim 1,
wherein the bonding pads include:
lower bonding pads exposed to an upper surface of a lower structure; and
upper bonding pads exposed to a lower surface of an upper structure.

7. The semiconductor device of claim 6, wherein the lower bonding pads overlap the upper bonding pads, respectively.

8. The semiconductor device of claim 6, wherein the upper bonding pads overlap the lower bonding pads, respectively.

9. The semiconductor device of claim 6,
wherein the lower structure includes:
lower bonding contacts contacting the lower bonding pads, respectively; and
lower lines each coupling at least two of the lower bonding contacts, and
wherein the upper structure includes:
upper bonding contacts contacting the upper bonding pads, respectively; and
upper lines each coupling at least two of the upper bonding contacts.

10. The semiconductor device of claim 9, wherein the circuit structure further includes the upper lines, the upper bonding contacts, the upper bonding pads, the lower bonding pads, the lower bonding contacts, and the lower lines coupled in series.

11. The semiconductor device of claim 10, wherein the upper lines, the upper bonding contacts, the upper bonding pads, the lower bonding pads, the lower bonding contacts, and the lower lines are coupled in a chain form.

12. The semiconductor device of claim 9, wherein the circuit structure further includes test electrodes electrically coupled to one or more of the upper lines.

13. The semiconductor device of claim 12, wherein information, on whether or not the lower structure and the upper structure are bonded to each other, is obtained through the test electrodes.

14. The semiconductor device of claim 9, wherein the circuit structure further includes the upper lines, the upper bonding contacts, the upper bonding pads, and the lower bonding pads coupled in series.

15. The semiconductor device of claim 14, wherein the upper lines, the upper bonding contacts, the upper bonding pads, and the lower bonding pads are coupled in a chain form.

16. The semiconductor device of claim 9, wherein the circuit structure further includes the upper bonding pads, the lower bonding pads, the lower bonding contacts, and the lower lines coupled in series.

17. The semiconductor device of claim 16, wherein the upper bonding pads, the lower bonding pads, the lower bonding contacts, and the lower lines are coupled in a chain form.

18. The semiconductor device of claim 6, wherein at least a portion of each of the upper bonding pads does not overlap the lower bonding pads.

19. The semiconductor device of claim 6, wherein at least a portion of each of the lower bonding pads does not overlap the upper bonding pads.

20. The semiconductor device of claim 6, wherein a length of each of the lower bonding pads is different from a length of each of the upper bonding pads in a horizontal direction.
